(19) United States
(12) Patent Application Publication
(10) Pub. No.: US 2020/0041666 A1
(43) Pub. Date: Feb. 6, 2020

(54) SEMICONDUCTOR MEMBRANE ENABLED HARD X-RAY DETECTORS

(71) Applicant: Wisconsin Alumni Research Foundation, Madison, WI (US)

(72) Inventors: Zhenqiang Ma, Middleton, WI (US); Zhenyang Xia, Madison, WI (US)

(21) Appl. No.: 16/055,577

(22) Filed: Aug. 6, 2018

(51) Int. Cl. G01T 1/20; H01L 25/16; H01L 31/107; G01T 1/161; G01T 1/24

(52) U.S. Cl. CPC G01T 1/2018; H01L 25/167; G01T 1/248; G01T 1/1612; H01L 31/107

(57) ABSTRACT

Micrometer-scale x-ray photodetectors that utilize a flexible array of photodiodes wrapped around the circumference of a scintillator core are provided. The photodetectors use dense and flexible pixelated arrays of photodiodes disposed around the circumference of a crystalline scintillator to provide highly compact photodetectors with high spatial, temporal, and energy resolution.

### REFERENCE TO GOVERNMENT RIGHTS

This invention was made with government support under DE-NA0002915 awarded by the U.S. Department of Energy. The government has certain rights in the invention.

### BACKGROUND

Conventional hard x-ray imaging devices are based on vacuum tube photomultipliers, which are bulky—generally having dimensions on the scale of tens of centimeters—and require a high voltage. As a result, the spatial resolution that can be achieved be these hard x-ray imaging devices is limited.

### SUMMARY

X-ray detectors that utilize a flexible array of photodiodes wrapped around the circumference of a scintillator core are provided. One embodiment of an x-ray detector includes: a crystalline scintillor having a circumference; and a flexible array of flexible avalanche photodiodes wrapped at least partially around the circumference of the crystalline scintillator. In some embodiments of the detectors, the crystalline scintiallors are cylindrical and the photodiodes of the photodioade array are disposed on a polymeric substrate. Depending upon the design of the photodiodes, the flexible array of photodiodes may be configured with the substrate facing toward or facing away from the scintillator core.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1A shows a schematic cross-sectional view of one embodiment of a flexible photodiode on a flexible substrate. FIG. 1B depicts in detail the parameters of the doping concentrations and layer thicknesses of the photodiode.

FIG. 1C shows a schematic cross-sectional view of another embodiment of a flexible photodiode on a flexible substrate. FIG. 1D depicts in detail the parameters of the doping concentrations and layer thicknesses of the photodiode.

FIG. 2 is a schematic diagram of an x-ray detector.

FIG. 3 is an illustration of x-ray detection by an x-ray detector.

FIG. 4A shows the results of a Monte-Carlo simulation of the photon generation (left panels) and the performance of the spatial resolution (right panels) for a photon source that randomly emits 10 photons.

FIG. 4B shows the results of a Monte-Carlo simulation of the photon generation (left panels) and the performance of the spatial resolution (right panels) for a photon source that randomly emits 30 photons.

FIG. 4C shows the results of a Monte-Carlo simulation of the photon generation (left panels) and the performance of the spatial resolution (right panels) for a photon source that randomly emits 60 photons.

### DETAILED DESCRIPTION

Micrometer-scale photodetectors that utilize a flexible array of photodiodes wrapped around the circumference of a scintillator core are provided. The photodetectors use dense and flexible pixelated arrays of photodiodes wrapped around the circumference of a crystalline scintillator to provide highly compact photodetectors with high spatial, temporal, and energy resolution.

In some embodiments, the photodiodes are avalanche photodiodes, including high-sensitivity single-photon detectors, which enable high detection efficiency and device flexibility. The photodiodes are formed from semiconductor epitaxial structures composed of multiple thin layers of single-crystalline semiconductor materials. The semiconductor layers are sufficiently thin to render the photodiodes mechanically flexible. Typically, the semiconductor layers in the epitaxial structures have thicknesses of 1 μm or less and the photodiodes have thicknesses of 5 μm or less. The flexible photodiode array, including the flexible substrate, can have a total thickness of 5 μm or less, but can also be thicker depending upon the thickness of the substrate. For example, the substrate may have a thickness of 1 μm or less but can be thicker—provided it remains mechanically flexible. By way of illustration, in some embodiments of the flexible photodiode arrays, the substrate has a thickness in the range from about 0.5 μm to about 50 μm, including substrates having a thickness in the range from about 0.5 μm to about 10 μm. The flexible photodiode arrays can be wrapped around highly curved scintillator crystals without significantly reducing the photo-responsivities of the photodiodes.

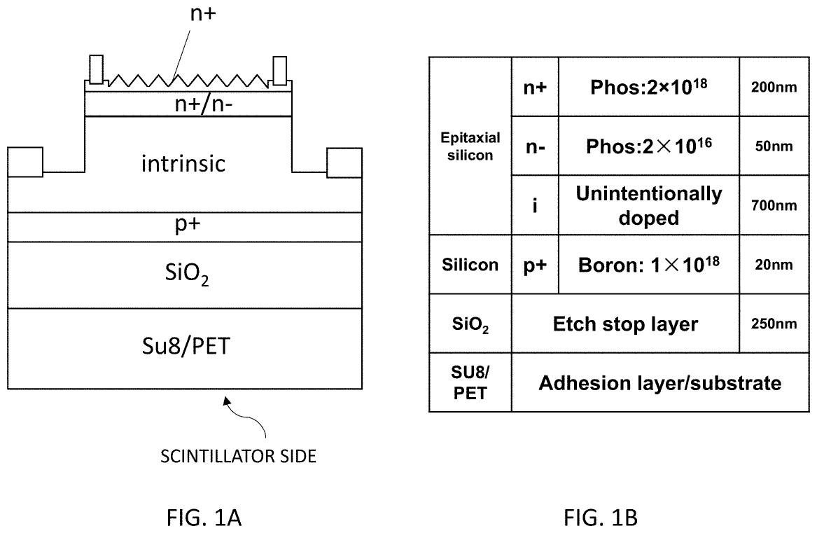

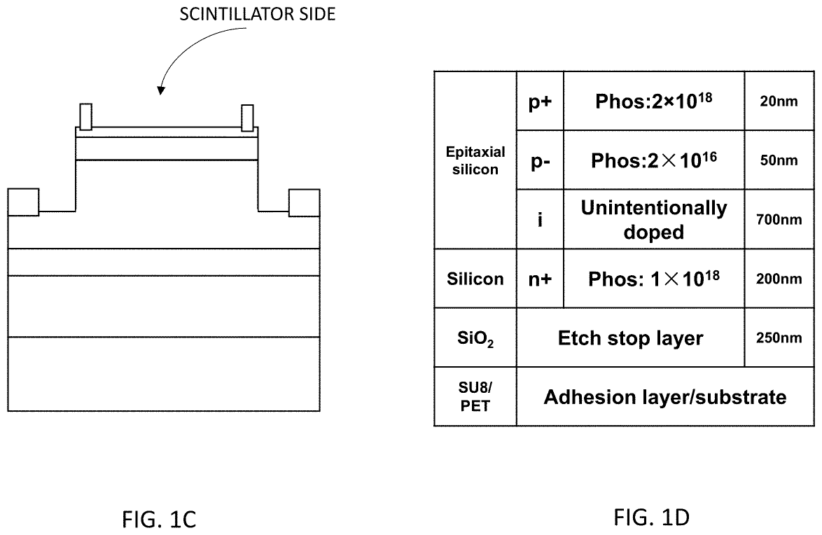

One embodiment of an avalanche photodiode on a flexible polymeric substrate is shown schematically in FIG. 1A. Exemplary materials, dopant concentrations, and layer thicknesses are shown in FIG. 1B. This photodiode is a p+-i-n photodiode that includes a p-type silicon region formed by the epitaxial growth of boron-doped silicon on a silicon-on-insulator (SOI) growth substrate. (Although not shown here, the p-type silicon region can, optionally, have a doping concentration gradient in which a lower layer is heavily p-type (p+) silicon and an upper layer is more lightly p-type doped (p) silicon. The use of a graded doping profile can enhance the carrier collection efficiency and photo responsivity of the diode in the ultraviolet wavelength region, as discussed in greater detail in Xia et al., Appl. Phys. Lett. 111, 081109 (2017).) A layer of unintentionally doped (intrinsic) silicon is disposed over the p-type region and an n-type region that includes a lower layer of phosphorus doped (n−) silicon and an upper contact layer of heavily phosphorus doped (n+) silicon is disposed over the unintentionally doped silicon. In the embodiment of the photodiode array shown here, a nano-cone structure is defined in the n+ layer. Methods for the epitaxial growth of photodiode heterostructures that include thin films of p-type and n-type doped silicon are described in Xia et al. The avalanche photodiode of FIG. 1A is attached to a flexible polymer (polyethylene terephthalate) substrate. A photodiode array would include a plurality of the photodiodes on the flexible polymeric substrate. A photodiode array including the photodiodes of FIGS. 1A and 1B would be designed to bonded substrate side down on a scintillator crystal.

Another embodiment of an avalanche photodiode on a flexible polymeric substrate is shown schematically in FIG. 1C. Exemplary materials, dopant concentrations, and layer thicknesses for this embodiment are shown in FIG. 1D. This photodiode is also a p+-i-n photodiode. It includes a n-type silicon region (n+) formed by the epitaxial growth of phosphorus-doped silicon on a silicon-on-insulator (SOI) growth substrate. A layer of unintentionally doped (intrinsic) silicon is disposed over the n-type region and a p-type region that includes a lower layer of boron doped (p−) silicon and an upper contact layer of heavily boron doped (p+) silicon is disposed over the unintentionally doped silicon. A photodiode array would include a plurality of the photodiodes on the flexible polymeric substrate. A photodiode array including the photodiodes of FIGS. 1C and 1D would be designed to bonded p-contact side down on a scintillator crystal.

The photodiode arrays can be assembled on a flexible substrate, such as a polymeric film, using semiconductor membrane transfer printing techniques. In the transfer printing techniques, one or more thin layers of semiconductor material are formed on a sacrificial substrate. That substrate is then selectively removed to release the one or more thin layers of semiconductor material (also referred to as semiconductor “nanomembranes” because they are so thin). The released layers are then transferred onto a flexible array substrate. A detailed illustration of the transfer printing process is described in Ma et al., Opt. Mater. Express 3, 1313 (2013). The semiconductor multilayer structures that make up the photodiodes can be fully formed using, for example, epitaxial growth on the sacrificial substrate prior to the release of the fully formed multilayer structures. Alternatively, the multilayer structure can be partially formed by growing one or more, but not all, of the semiconductor layers that make up the structure on the sacrificial substrate prior to release and then forming the remaining semiconductor structures after the release of the one or more semiconductor layers.

The method of forming and transferring partially- or fully-formed photodiode multilayer structures onto a flexible array substrate can be carried out starting with a semiconductor-on-insulator (“SOT”) substrate comprised of a handle wafer, a buried oxide (“BOX”) layer, and a thin layer of single-crystalline semiconductor (a device layer). One or more semiconductor heterostructures can be formed on the device layer via epitaxial growth, lithography, and self-assembly, as illustrated in the Example. These layers can include p-type and n-type contact layers, and the light absorption and pn junction layers that makes up the avalanche region of the diode. Other photodiode device components can also be formed at this stage, including nano-cone (i.e., inverted pyramid) arrays for increased light-trapping and absorption and electrical contacts, which can be formed via standard metallization processes. The photodiode multilayer structures can then be mounted to a temporary host substrate and the handle wafer can be removed using, for example, mechanical grinding and/or etching. The removal of the handle wafer releases the photodiode multilayer structures together with the device layer and buried oxide layer on which they are formed and allows the released structure to be transferred onto and bonded to a flexible array substrate, such as a polymeric film.

A detailed, illustrative process for forming silicon avalanche photodiodes and transfer bonding the photodiodes to a flexible polymeric substrate is provided in the Example. However, other semiconductor materials can be used in the photodiodes, including silicon carbide (SiC), germanium (Ge), and gallium arsenide (GaAs). By way of illustration, methods for forming SiC nanomembranes for use as ultraviolet detectors using transfer printing techniques can be found in Kim et al., J. Mater. Chem. C, 2017, 5, 264.

The photodiodes can be assembled onto the flexible arrays substrate with high densities. By way of illustration, some embodiments of the flexible arrays of flexible photodiodes have a photodiode density of at least 100 photodiodes per mm² on the array substrate. For example, embodiments of the arrays can have a photodiode density in the range from 100 to 10,000 photodiodes per mm². Optionally, the photodiodes of the array can be separated by a material that provides optical isolation. Reflective materials, such as metals or photonic crystals can be used for this purpose.

The transfer printing process enables the formation of photodiode arrays that include photodiodes made from different semiconductor materials and that have different absorption and photoemission spectra. By way of illustration, photodiodes comprising silicon nanomembranes and photodiodes comprising silicon carbide nanomembranes can be combined in the same photodiode array. This design enables the array to include different detectors to detect radiation of different wavelengths.

Once formed, the flexible photodiode array can be fixed to the surface of a scintillator crystal. An optically transparent bonding agent, such as a grease, can be used to bond the array to the crystal. Because the photodiode arrays are flexible, they can be wrapped around the circumference of even highly curved scintillator crystals. Thus, the flexible photodiode arrays can be disposed on the surface of a scintillator having a circumference that defines an arc with a low radius of curvature and the array substrate and photodiodes can conform to the curvature of the surface. In some embodiments of the detectors, the scintillator crystal is cylindrical and has a circular circumference with a radius of 100 mm or smaller. This includes cylindrical scintillator crystals having radii of than 50 mm or smaller. For example, the radii of the scintillator crystals can be in the range from 5 mm to 50 mm. However, the crystals need not be cylindrical with a circular circumference. The scintillator crystals may be a slab. For example, the scintillator crystals may take the form of hollow tubes. The use of hollow scintillator crystals may be useful for applications where it is desirable to pass an x-ray radiation source through the detector.

The flexible photodiode array can be disposed on only a portion of the circumference of the crystal or can be wrapped around the full circumference. For example, the flexible photodiode array can be wrapped around at least half the circumference of the scintillator, at least 75% of the circumference, or at least 95% of the circumference.

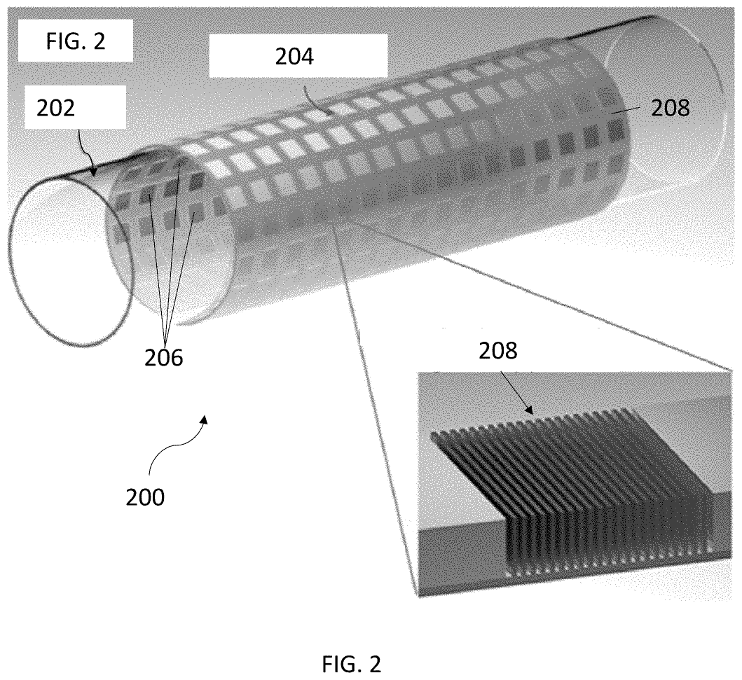

FIG. 2 is a schematic diagram of a photodetector 200 that includes a cylindrical crystalline scintillator 202 having a flexible diode array 204 wrapped around its circumference. Crystalline scintillator can be, for example, BaF₂ or NaI. The flexible diode array includes a plurality of thin photodiodes 206 on a flexible array substrate 208. As shown in the figure, flexible diode array 204 can be disposed around the outer surface of scintillator 202 with the light-absorbing surfaces of photodiodes 206 facing scintillator 202. In the embodiment shown here, individual photodiodes are optically isolated by providing photonic crystals 208 of high photonic band-gap semiconductor materials between the photodiodes.

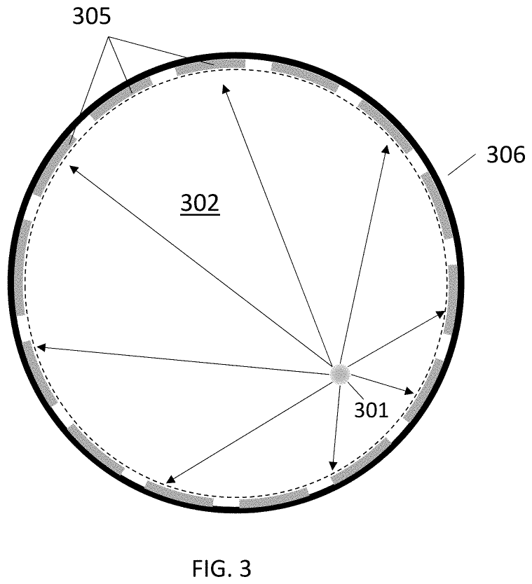

During operation, incident x-ray radiation from a radiation source is absorbed by the scintillator crystal and is converted into optical photons with energies in the wavelength from ultraviolet to visible regions of the electromagnetic spectrum. (Usually in the range from about 200 nm to about 500 nm.) The optical photons are then absorbed by the light-absorption layers of the photodiodes, which operate near the breakdown voltage under a reverse bias, to generate detectable electrical signals. This is illustrated in FIG. 3, which shows the absorption of an x-ray 301 in a cylindrical scintillator crystal 302. The absorption event results in the creation of optical photons (represented by arrows) that are detected by the photodiodes 305 of a photodiode array 306 that is wrapped around the circumference (black, dashed line) of scintillator crystal 302. The location in the scintillator crystal where the x-ray deposits its energy and the time of the energy deposition can be determined based on which photodiodes generate a corresponding electrical signal and the timing of the signal. Because the detectors can be made with micrometer-scale dimensions with a high density, pixilated diode array, both a high spatial resolution and a high temporal resolution can be achieved. In addition, because the penetration depth of the x-ray in the scintillator crystal can be determined, the detectors also provide high energy resolution.

### EXAMPLES

### Example 1

This example describes a process for the fabrication of a flexible avalanche photodiode of FIG. 1A and FIG. 1B on a flexible substrate. The fabrication started with a 4-inch silicon-on-insulator (SOI) wafer. Chemical vapor deposition (CVD) was used for the epitaxial growth (epi-growth) of phosphorus-doped (n-type), intrinsic, and boron-doped (p-type) layers of silicon on a silicon-on-insulator (SOI) wafer. An array of avalanche photodiodes (APDs) was then fabricated into the epi-grown layers. The process included nano-cone array fabrication on the surfaces of the photodiodes by self-assembly of colloidal nanoparticles, followed by a subsequent wet etching process, as described in K Zang et al, Nat. Commun. 8, 628 (2017). The parameters of the square patterned inverse pyramids (“nano-cones”) were 850 nm of period and 600 nm of depth. A standard nano-fabrication process was used to define the photo detection mesa and metalize (Al/Au) the photodiodes via magnetron sputtering. Then the device side was protected by spin coating a photoresist and flip-mounting onto a polydimethylsiloxane (PDMS) substrate. A substrate grinding process thinned down the silicon substrate to a thickness of 100 μm, and then further thinned it down by the XeF₂ etching process. The etching rate was about 3 μm/min. The etching terminated at the silicon dioxide layer. The sample was then attached to a polyethylene terephthalate (PET) layer using SU8 epoxy-based photoresist as an adhesion layer. After curing the SU8 using UV exposure and post-baking, a standard cleaning process (acetone/isopropyl alcohol (IPA)/deionized (DI) water) was used to detach the PDMS and remove the protected photoresist. To ensure that the device was well-protected during the fabrication process, the dark current and LED white light responses were measured on the same device before and after the nanomembrane transfer process. The dark current was negligible, and the photoresponse became better due to larger index contrast of each layer.

To analyze the absorption performance of the flexible photodetector, Fourier Transform Infrared (FTIR) spectroscopy was used to measure the reflectance and transmittance of the device. In order to demonstrate an avalanche photodiode with wide angle detection under different bending conditions, the mesa was defined at a diameter of 500 μm. Then, the finished avalanche photodiode was flipped and mounted onto the PDMS to remove the silicon substrate, as described above. The first step of substrate removal was the grinding process to reduce the substrate thickness from 1 mm to 100 μm. The device was then rinsed with DI water and etched by XeF₂ to remove the rest of the silicon substrate. The device was mounted on the PDMS, and then transferred onto the PET substrates.

The photodiode was tested under different bending conditions, controlled by a lab-made stretcher. First, the light signal was fixed and the device was bent to a curvature of 6 mm. The photoresponse did not change in different bending conditions, demonstrating that the device structure was well-suited for use in a flexible working environment. The device was then fixed under a curvature of 6 mm and the light signal was moved. The device exhibited high and uniform performance as a function of the light source angle.

### Example 2

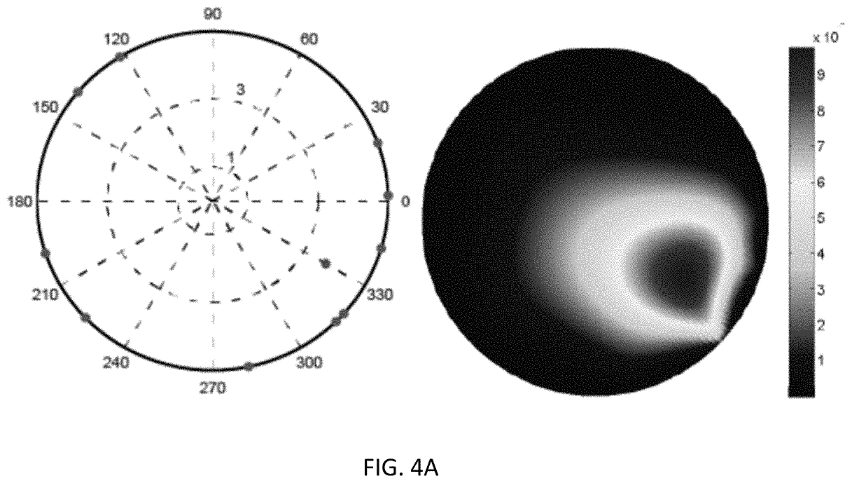

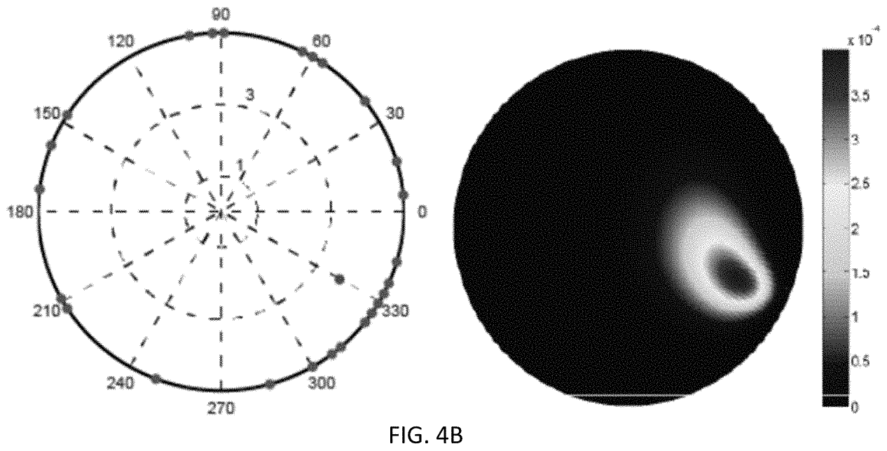

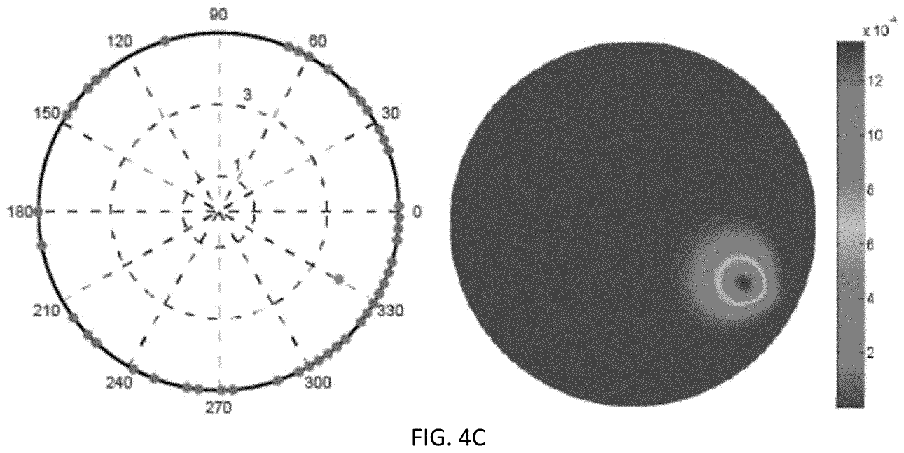

This example describes the results of Monte-Carlo simulations of an X-ray detector as described herein. In the simulation, the Monte-Carlo method was used to simulate the emission of 10, 30, and 60 photons, as shown in FIGS. 4A, 4B, and 4C, respectively. On the left panel of each figure, the location of the x-ray absorption in a cylindrical scintillator crystal (represented by a dark circle) is indicated by the dot in inside the circle and the detection of the photons by the photodiodes in the array are indicated by the dots on the circle. The location of pixelated photodiodes was the only information fed into the algorithms. The right panel in each of the figures shows the probability distribution of the x-ray source location calculated using a Bayesian analysis. The position of highest probability was interpreted as the source location. In this approach, there was no limit in terms of the calculated resolution. However, the accuracy of the estimate depended on the number of photons. For the simulated cases, the estimated positions for the 10, 30, and 60 photons differed from the actual positions by 180, 85, and 37 micrometers, respectively. Thus, it can be seen that the accuracy increased with more photons.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

1. An x-ray detector comprising:
a scintillator crystal having a circumference; and
a flexible array of flexible avalanche photodiodes wrapped at least partially around, and bonded to, the circumference of the scintillator crystal.

2. The detector of claim 1, wherein a circumference of the scintillator crystal defines an arc and the flexible array of avalanche photodiodes is disposed on a portion of the circumference of the scintillator crystal that defines the arc and the avalanche photodiodes conform to the curvature of the arc.

3. The detector of claim 2, wherein the scintillator crystal is cylindrical.

4. The detector of claim 3, wherein the flexible array of avalanche photodiodes is wrapped around at least half of the circumference of the scintillator crystal.

5. The detector of claim 3, wherein the flexible array of avalanche photodiodes is wrapped around the full circumference of the scintillator crystal.

6. The detector of claim 1, wherein the array of avalanche photodiodes comprises silicon avalanche photodiodes.

7. The detector of claim 1, wherein the array of avalanche photodiodes comprises SiC avalanche photodiodes.

8. The detector of claim 1, wherein the flexible array of avalanche photodiodes comprises a polymeric substrate and the polymeric substrate is adhered to the scintillator crystal.

9. The detector of claim 1, wherein the flexible array of avalanche photodiodes comprises at least two different kinds of avalanche photodiodes, wherein the different kinds of avalanche photodiodes have different ultraviolet radiation absorption spectra.

10. The detector of claim 1, wherein the flexible array of avalanche photodiodes has an avalanche photodiode density of at least 100 photodiodes/mm².

11. The detector of claim 1, wherein the flexible array of avalanche photodiodes has an avalanche photodiode density of at least 1000 photodiodes/mm².

12. The detector of claim 1, wherein the circumference of the scintillator crystal is curved and the avalanche photodiodes conform to the curvature of the circumference of the scintillator crystal.

13. The detector of claim 12, wherein the scintillator crystal is cylindrical.

14. The detector of claim 13, wherein the cylindrical scintillator crystal has a radius of 10 mm or smaller.

15. The detector of claim 4, wherein the flexible array of avalanche photodiodes has an avalanche photodiode density of at least 100 photodiodes/mm².

16. The detector of claim 1, wherein the flexible avalanche photodiodes have thicknesses of no greater than 5 μm.

17. The detector of claim 1, wherein the scintillator crystal is cylindrical, but is not a hollow tube.

18. The detector of claim 12, wherein the flexible avalanche photodiodes comprise multiple layers of single-crystalline semiconductor materials, wherein the multiple layers of single-crystalline semiconductor materials conform to the curvature of the circumference of the scintillator crystal.

19. The detector of claim 18, wherein the multiple layers of single-crystalline semiconductor materials include layers of single-crystalline silicon.

20. The detector array of claim 19, wherein the scintillator crystal is a cylindrical scintillator crystal having a radius of 10 mm or smaller.
